(19) United States
(12) Patent Application Publication
(10) Pub. No.: US 2026/0164963 A1
(43) Pub. Date: Jun. 11, 2026

(54) PIXEL CIRCUIT, DISPLAY DEVICE COMPRISING PIXEL CIRCUIT, AND ELECTRONIC DEVICE COMPRISING DISPLAY DEVICE

(71) Applicant: Samsung Display Co., Ltd., Yongin-si (KR)

(72) Inventors: Sun Kwun SON, Yongin-si (KR); Dong Hee SHIN, Yongin-si (KR); Na Hyeon CHA, Yongin-si (KR)

(21) Appl. No.: 19/180,784

(22) Filed: Apr. 16, 2025

(30) Foreign Application Priority Data
Jun. 17, 2024 (KR) 10-2024-0078348
Jul. 17, 2024 (KR) 10-2024-0094635

(51) Int. Cl. H10K 59/131; H10K 59/121; H10K 59/123

(52) U.S. Cl. CPC H10K 59/131; H10K 59/1213; H10K 59/1216; H10K 59/123

(57) ABSTRACT

A display device includes: a sub-pixel circuit on a substrate and comprising an N-type transistor and a P-type transistor, each including a first transistor electrode region and a second transistor electrode region, and a connection electrode; and a light-emitting element electrically connected to the sub-pixel circuit, wherein the substrate comprises a well including an N-type well and a P-type well that overlap each other in a plan view, the first transistor electrode region and the second transistor electrode region of the P-type transistor are P-type regions formed in the N-type well, the first transistor electrode region and the second transistor electrode region of the N-type transistor are N-type regions formed in the P-type well, and the connection electrode electrically connects the first transistor electrode region of the P-type transistor and the second transistor electrode region of the N-type transistor.

### CROSS-REFERENCE TO RELATED APPLICATION

The present application claims priority to and the benefit of Korean Patent Application No. 10-2024-0078348, filed on Jun. 17, 2024, and Korean Patent Application No. 10-2024-0094635, filed on Jul. 17, 2024, in the Korean Intellectual Property Office, the entire disclosures of each of which are incorporated herein by reference.

### BACKGROUND

### 1. Field

Aspects of some embodiments of the present disclosure relate to a pixel circuit, a display device including the pixel circuit, and an electronic device comprising the display device.

### 2. Description of the Related Art

As interest in information displays has grown recently, research and development on display devices are being conducted continuously.

A display device generally includes light-emitting elements capable of emitting light and pixel circuits for operating the light-emitting elements. In order to relatively improve the resolution characteristics of the display device, it may be desirable to pattern a pixel circuit in a relatively small area.

The above information disclosed in this Background section is only for enhancement of understanding of the background and therefore the information discussed in this Background section does not necessarily constitute prior art.

### SUMMARY

Aspects of some embodiments of the present disclosure include a pixel circuit, a display device including the pixel circuit, and an electronic device comprising the display device, which can have high-resolution characteristics.

Aspects of some embodiments of the present disclosure include a pixel circuit, a display device including the pixel circuit, and an electronic device comprising the display device, in which the area required for circuit elements to be arranged can be relatively reduced.

According to some embodiments of the present disclosure, a display device may include a sub-pixel circuit formed on a substrate and including an N-type transistor and a P-type transistor, each including a first transistor electrode region and a second transistor electrode region, and a connection electrode; and a light-emitting element electrically connected to the sub-pixel circuit. According to some embodiments, the substrate may include a well including an N-type well and a P-type well that overlap each other in a plan view. According to some embodiments, the first transistor electrode region and the second transistor electrode region of the P-type transistor may be P-type regions formed in the N-type well. According to some embodiments, the first transistor electrode region and the second transistor electrode region of the N-type transistor may be N-type regions formed in the P-type well. According to some embodiments, the connection electrode may electrically connect the first transistor electrode region of the P-type transistor and the second transistor electrode region of the N-type transistor.

According to some embodiments, the P-type well may be on the N-type well.

According to some embodiments, the first transistor electrode region may be a source region. According to some embodiments, the second transistor electrode region may be a drain region. According to some embodiments, the P-type transistor may include a first gate electrode. According to some embodiments, the N-type transistor may include a second gate electrode. According to some embodiments, the first gate electrode may be between the N-type well and the P-type well.

According to some embodiments, the first gate electrode and the second gate electrode may overlap each other in a plan view.

According to some embodiments, the first gate electrode may be between the first transistor electrode region and the second transistor electrode region of the N-type transistor in a plan view.

According to some embodiments, the second gate electrode may be between the first transistor electrode region and the second transistor electrode region of the P-type transistor in a plan view.

According to some embodiments, the connection electrode may form at least a portion of a node that electrically connects the N-type transistor and the P-type transistor. According to some embodiments, no other transistor may be formed between the N-type transistor and the P-type transistor.

According to some embodiments, the connection electrode may be on the substrate, and may be on an interlayer insulating layer covering the second gate electrode.

According to some embodiments, the connection electrode may include a first portion extending in a second direction and electrically connected to the first transistor electrode region of the P-type transistor, a second portion extending in the second direction and electrically connected to the second transistor electrode region of the N-type transistor, and a third portion extending in a first direction different from the second direction and connecting the first portion and the second portion.

According to some embodiments, the first gate electrode and the second gate electrode may extend in the second direction.

According to some embodiments, the first portion of the connection electrode may be electrically connected to the first transistor electrode region of the P-type transistor through a first contact part. According to some embodiments, the second portion of the connection electrode may be electrically connected to the second transistor electrode region of the N-type transistor through a second contact part.

According to some embodiments, a portion of the first transistor electrode region of the P-type transistor may overlap a portion of the first transistor electrode region of the N-type transistor in a plan view. According to some embodiments, another portion of the first transistor electrode region of the P-type transistor may not overlap at least another portion of the first transistor electrode region of the N-type transistor in a plan view.

According to some embodiments, a portion of the second transistor electrode region of the N-type transistor may overlap a portion of the second transistor electrode region of the P-type transistor in a plan view. According to some embodiments, another portion of the second transistor electrode region of the N-type transistor may not overlap at least another portion of the second transistor electrode region of the P-type transistor in a plan view.

According to some embodiments, the sub-pixel circuit may include a first sub-pixel circuit, a second sub-pixel circuit, and a third sub-pixel circuit, each of which includes circuit elements including the N-type transistor and the P-type transistor and which are adjacent to each other along a first direction. According to some embodiments, the circuit elements may be arranged along a second direction different from the first direction in each of the first sub-pixel circuit, the second sub-pixel circuit, and the third sub-pixel circuit.

According to some embodiments, the display device may further include a first power line, a second power line, a third power line, and a data line that are electrically connected to the sub-pixel circuit. According to some embodiments, the first power line may form a first power supply voltage node, and the second power line may form a second power supply voltage node. According to some embodiments, the P-type transistor may be a P-channel Metal-Oxide-Semiconductor (PMOS). According to some embodiments, the N-type transistor may be an N-channel Metal-Oxide-Semiconductor (NMOS). According to some embodiments, the sub-pixel circuit may include a first transistor, a second transistor, a third transistor, a fourth transistor, a fifth transistor, and a sixth transistor. According to some embodiments, the first transistor may be connected between the fifth transistor and a first node. According to some embodiments, the second transistor may be electrically connected to the data line. According to some embodiments, the third transistor may be connected between a second node electrically connected to a gate electrode of the first transistor and the first node. According to some embodiments, the fourth transistor may be connected between a third node electrically connected to an anode electrode of the light-emitting element and the first node. According to some embodiments, the fifth transistor may be connected between the first transistor and the first power line. According to some embodiments, the sixth transistor may be connected between the third node and the third power line. According to some embodiments, a cathode electrode of the light-emitting element may be connected between the second power line and the third node. The fourth transistor may be the P-type transistor. According to some embodiments, the sixth transistor may be the N-type transistor.

According to some embodiments, the P-type transistor and the N-type transistor may overlap in an overlap area in a plan view. According to some embodiments, the first transistor, the second transistor, the third transistor, and the fifth transistor may be located on one side of the overlap area.

According to some embodiments, the first transistor, the second transistor, the third transistor, and the fifth transistor may not be located on the other side of the overlap area along the second direction.

According to some embodiments, no other transistor may be formed between the fourth transistor and the sixth transistor.

According to some embodiments, the sub-pixel circuit may further include a first capacitor connected between the second transistor and the second node; and a second capacitor connected between the first power supply voltage node and the second node. According to some embodiments, each of the first transistor, the second transistor, the third transistor, the fourth transistor, the fifth transistor, and the sixth transistor may include a body electrode mounted on the substrate and electrically connected to the first power line. According to some embodiments, the display device may be an OLEDoS (OLED on Silicon) display device.

According to some embodiments of the present disclosure, a pixel circuit may include a P-type transistor including a first gate electrode; and an N-type transistor including a second gate electrode. According to some embodiments, no other transistor may be formed between the N-type transistor and the P-type transistor, and the N-type transistor and the P-type transistor may be electrically connected through one node. According to some embodiments, the first gate electrode and the second gate electrode may overlap each other in a plan view.

According to some embodiments of the present disclosure, an electronic device may comprise a processor configured to provide input image data; a display device configured to display an image based on the input image data, the display device including sub-pixel areas; and a power supply configured to supply power to the display device. The display device may comprise: a sub-pixel circuit on a substrate and comprising an N-type transistor and a P-type transistor, each including a first transistor electrode region and a second transistor electrode region, and a connection electrode; and a light-emitting element electrically connected to the sub-pixel circuit. The substrate may comprise a well including an N-type well and a P-type well that overlap each other in a plan view. The first transistor electrode region and the second transistor electrode region of the P-type transistor may be P-type regions formed in the N-type well. The first transistor electrode region and the second transistor electrode region of the N-type transistor may be N-type regions formed in the P-type well. The connection electrode may electrically connect the first transistor electrode region of the P-type transistor and the second transistor electrode region of the N-type transistor.

According to some embodiments of the present disclosure, a pixel circuit, a display device including the pixel circuit, and an electronic device comprising the display device, which can have high-resolution characteristics, can be provided.

According to some embodiments of the present disclosure, a pixel circuit, a display device including the pixel circuit, and an electronic device comprising the display device, in which the area required for circuit elements to be located can be relatively reduced, can be provided.

### BRIEF DESCRIPTION OF THE DRAWINGS

FIG. 1 is a block diagram showing aspects of a display device according to some embodiments;

FIG. 2 is a block diagram showing aspects of one of the sub-pixels of FIG. 1 according to some embodiments;

FIG. 3 is a schematic diagram showing a sub-pixel circuit and a sub-pixel including a same according to some embodiments;

FIG. 4 is a plan view showing aspects of the display panel of FIG. 1 according to some embodiments;

FIG. 5 is an exploded perspective view showing aspects of a portion of the display panel of FIG. 4 according to some embodiments;

FIG. 6 is a schematic cross-sectional view showing aspects of a pixel-circuit layer according to some embodiments;

FIG. 7 is a diagram schematically showing adjacent sub-pixels and sub-pixel circuits according to some embodiments;

FIG. 8 is a schematic plan view showing a display device in an overlap area according to some embodiments;

FIGS. 9 and 10 are schematic cross-sectional views showing a display device in an overlap area according to some embodiments;

FIG. 11 is a block diagram showing aspects of an electronic device according to some embodiments;

FIG. 12 is a perspective view showing an application example of the electronic device of FIG. 11 according to some embodiments; and

FIG. 13 is a diagram showing the head-mounted display worn by a user of FIG. 12 according to some embodiments.

### DETAILED DESCRIPTION

Because embodiments according to the present disclosure can be modified in various ways and take multiple forms, aspects of some embodiments will be illustrated in the drawings and described herein in more detail. However, this is not intended to limit the disclosure to any particular disclosed forms, and should be understood to include all modifications, equivalents, and alternatives that fall within the spirit and scope of the disclosure.

Terms such as first and second may be used to describe various components, but the components should not be limited by such terms. The terms are used only for the purpose of distinguishing one component from another. For example, a first component may be named a second component, and similarly, a second component may also be named a first component, without departing from the scope of the disclosure. A singular expression includes a plural expression unless the context clearly indicates otherwise.

In the disclosure, it should be understood that terms such as “comprise” or “have” are intended to specify the presence of features, numbers, steps, operations, components, parts, or combinations thereof described in the specification, and not to preclude the possibility of the presence or addition of one or more other features, numbers, steps, operations, components, parts, or combinations thereof. In addition, when a portion of a layer, film, area, plate, or the like is said to be “on” another portion, this includes not only the case where the portion is “directly on” said another portion, but also the case where there is another portion in-between. Further, in the present specification, when a portion of a layer, film, area, plate, or the like is said to be formed on another portion, the direction in which the portion is formed is not limited to the upward direction, but also includes forming in the lateral or downward direction. On the other hand, when a portion of a layer, film, area, plate, or the like is said to be “under” another portion, this includes not only the case where the portion is “directly under” said another portion, but also the case where there is another portion in-between.

Aspects of some embodiments of the present disclosure relate to a pixel circuit, a display device including the pixel circuit, and an electronic device comprising the display device. Hereinafter, a pixel circuit, a display device including the pixel circuit, and an electronic device comprising the display device according to some embodiments will be described in more detail with reference to the accompanying drawings.

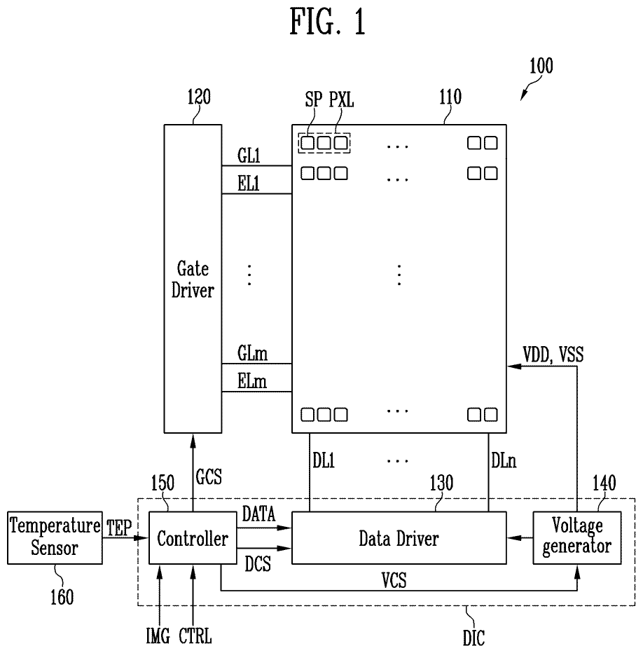

FIG. 1 is a block diagram showing aspects of a display device according to some embodiments.

Referring to FIG. 1, a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

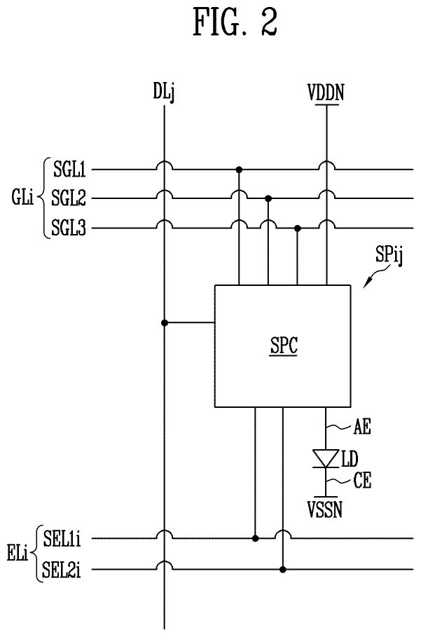

Each of the sub-pixels SP may include at least one light-emitting element LD (see FIG. 2) configured to generate light. Accordingly, each of the sub-pixels SP may generate light of a particular color, such as red, green, blue, cyan, magenta, yellow, etc. Two or more of the sub-pixels SP may form a single pixel PXL. For example, three sub-pixels SP may form (e.g., constitute) a single pixel PXL as shown in FIG. 1. Collectively, the pixels PXL, and their sub-pixels SP, may generate or display images based on data signals and gate/scan signals.

The gate driver 120 is electrically connected to the sub-pixels SP arranged in the row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating the start of each frame, a horizontal synchronization signal for outputting gate signals in synchronization with the timing at which data signals are applied, and the like.

According to some embodiments, first to m-th light emission control lines EL1 to ELm connected to the sub-pixels SP in the row direction may be further provided. In this case, the gate driver 120 may include a light emission control driver configured to control the first to m-th light emission control lines EL1 to ELm, and the light emission control driver may operate under the control of the controller 150.

The gate driver 120 may be located on one side of the display panel 110. However, embodiments according to the present disclosure are not limited thereto. For example, the gate driver 120 may be divided into two or more drivers that are distinct physically and/or logically, and such drivers may be located on one side of the display panel 110 and the other side of the display panel 110 opposite to the one side. In this way, the gate driver 120 may be arranged around (e.g., in a periphery or outside a footprint of a display area of) the display panel 110 in various forms according to embodiments.

The data driver 130 is connected to the sub-pixels SP arranged in the column direction through the first to n-th data lines DL1 to DLn. The data driver 130 receives image data DATA and a data control signal DCS from the controller 150. The data driver 130 operates in response to the data control signal DCS. According to some embodiments, the data control signal DCS may include a source start pulse, a source shift clock, a source output enable signal, etc.

The data driver 130 may apply data signals having gradation voltages corresponding to the image data DATA to the first to n-th data lines DL1 to DLn by using voltages from the voltage generator 140. When a gate signal is applied to each of the first to m-th gate lines GL1 to GLm, data signals corresponding to the image data DATA may be applied to the first to n-th data lines DL1 to DLn. Accordingly, the corresponding sub-pixels SP may generate light corresponding to the data signals. Accordingly, images are displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to the components of the display device 100. For example, the voltage generator 140 may be configured to generate a plurality of voltages by receiving an input voltage from outside the display device 100, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a voltage level lower than the first power supply voltage VDD. According to some embodiments, the first power supply voltage VDD or the second power supply voltage VSS may be provided by an external device of the display device 100.

The voltage generator 140 may generate a variety of voltages. For example, the voltage generator 140 may generate an initialization voltage to be applied to the sub-pixels SP. For example, during a sensing operation for sensing electrical characteristics of the transistors and/or light-emitting elements of the sub-pixels SP, one reference voltage may be applied to the first to n-th data lines DL1 to DLn, and the voltage generator 140 may generate such a reference voltage.

The controller 150 controls all operations of the display device 100. The controller 150 receives input image data IMG from the outside and a control signal CTRL for controlling the display thereof. The controller 150 may provide a gate control signal GCS, a data control signal DCS, and a voltage control signal VCS in response to the control signal CTRL.

The controller 150 may convert the input image data IMG to fit the display device 100 or the display panel 110 and output image data DATA. According to some embodiments, the controller 150 may align the input image data IMG to fit the sub-pixels SP of a row unit and output image data DATA.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In such a case, the data driver 130, the voltage generator 140, and the controller 150 may be functionally distinct components within a single driver integrated circuit DIC. According to some embodiments, at least one of the data driver 130, the voltage generator 140, or the controller 150 may be provided as a component separate from the driver integrated circuit DIC.

The display device 100 may include at least one temperature sensor 160. The temperature sensor 160 is configured to sense the temperature of its surroundings and generate temperature data TEP representing the sensed temperature. According to some embodiments, the temperature sensor 160 may be located adjacent to the display panel 110 and/or the driver integrated circuit DIC.

The controller 150 may control various operations of the display device 100 in response to the temperature data TEP. According to some embodiments, the controller 150 may adjust the brightness of an image outputted from the display panel 110 in response to the temperature data TEP. For example, the controller 150 may adjust the data signals and the first and second power supply voltages VDD and VSS by controlling components such as the data driver 130 and/or the voltage generator 140.

FIG. 2 is a block diagram showing aspects of one of the sub-pixels of FIG. 1 according to some embodiments. In FIG. 2, a sub-pixel SPij arranged in the i-th row (where i is an integer greater than or equal to 1 and less than or equal to m) and the j-th column (where j is an integer greater than or equal to 1 and less than or equal to n) of the sub-pixels SP in FIG. 1 is shown by way of example.

Referring to FIG. 2, the sub-pixel SPij may include a sub-pixel circuit SPC and a light-emitting element LD.

The light-emitting element LD is connected between a first power supply voltage node VDDN and a second power supply voltage node VSSN. In this case, the first power supply voltage node VDDN is a node that transmits the first power supply voltage VDD of FIG. 1, and the second power supply voltage node VSSN is a node that transmits the second power supply voltage VSS of FIG. 1.

The anode electrode AE of the light-emitting element LD may be connected to the first power supply voltage node VDDN through the sub-pixel circuit SPC, and the cathode electrode CE of the light-emitting element LD may be connected to the second power supply voltage node VSSN. For example, the anode electrode AE of the light-emitting element LD may be connected to the first power supply voltage node VDDN through one or more transistors included in the sub-pixel circuit SPC.

The sub-pixel circuit SPC may be connected to the i-th gate line GLi of the first to m-th gate lines GL1 to GLm of FIG. 1, the i-th light emission control line ELi of the first to m-th light emission control lines EL1 to ELm of FIG. 1, and the j-th data line DLj of the first to n-th data lines DL1 to DLn of FIG. 1. The sub-pixel circuit SPC is configured to control the light-emitting element LD according to signals received through these signal lines.

In the present specification, the sub-pixel circuit SPC may also be referred to as a pixel circuit.

The sub-pixel circuit SPC may operate in response to a gate signal received through the i-th gate line GLi. The i-th gate line GLi may include one or more sub-gate lines. According to some embodiments, the i-th gate line GLi may include first to third sub-gate lines SGL1 to SGL3 as shown in FIG. 2. The sub-pixel circuit SPC may operate in response to gate signals received through the first to third sub-gate lines SGL1 to SGL3. As such, if the i-th gate line GLi includes two or more sub-gate lines, the sub-pixel circuit SPC may operate in response to gate signals received through the corresponding sub-gate lines.

The sub-pixel circuit SPC may operate in response to a light emission control signal received through the i-th light emission control line ELi. According to some embodiments, the i-th light emission control line ELi may include one or more sub-light emission control lines. For example, the i-th light emission control line ELi may include a first sub-light emission control line SEL1i and a second sub-light emission control line SEL2i. The sub-pixel circuit SPC may operate in response to light emission control signals received through the first sub-light emission control line SEL1i and the second sub-light emission control line SEL2i.

The sub-pixel circuit SPC may receive a data signal through the j-th data line DLj. The sub-pixel circuit SPC may store a voltage corresponding to the data signal in response to at least one of the gate signals received through the first to third sub-gate lines SGL1 to SGL3. The sub-pixel circuit SPC may adjust the current flowing from the first power supply voltage node VDDN to the second power supply voltage node VSSN through the light-emitting element LD according to the stored voltage, in response to the light emission control signals received through the first sub-light emission control line SEL1i and the second sub-light emission control line SEL2i. Accordingly, the light-emitting element LD may generate light of a brightness corresponding to the data signal.

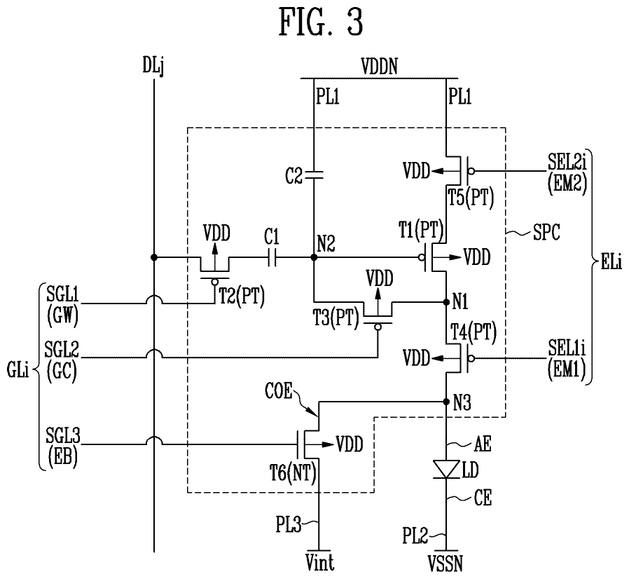

FIG. 3 is a schematic diagram showing a sub-pixel circuit and a sub-pixel including a same according to some embodiments. For convenience of description, FIG. 3 shows a sub-pixel SPij located on the i-th horizontal line and the j-th vertical line of the sub-pixels SP as in FIG. 2. Although FIG. 3 illustrates various components in a sub-pixel circuit according to some embodiments of the present disclosure, embodiments according to the present disclosure are not limited thereto, and according to various embodiments, the sub-pixel circuit may include additional components or fewer components without departing from the spirit and scope of embodiments according to the present disclosure.

Referring to FIG. 3, the sub-pixel circuit SPC may include a first transistor T1, a second transistor T2, a third transistor T3, a fourth transistor T4, a fifth transistor T5, and a sixth transistor T6. The sub-pixel circuit SPC may include a first capacitor C1 and a second capacitor C2.

The light-emitting element LD may include an anode electrode AE and a cathode electrode CE. The light-emitting element LD may be connected between a third node N3 and a second power line PL2. The anode electrode AE may be electrically connected to the sub-pixel circuit SPC through the third node N3, and may be electrically connected to a first power line PL1 that supplies the first power supply voltage VDD. The cathode electrode CE may be electrically connected to the second power line PL2 that supplies the second power supply voltage VSS.

According to some embodiments, the first to sixth transistors T1 to T6 may include a body electrode. For example, the first to sixth transistors T1 to T6 may be MOSFETs (metal oxide semiconductor field effect transistors). In this case, the first to sixth transistors T1 to T6 can be mounted in a small area, and accordingly, the sub-pixel SPij may be applied to a high-resolution panel. According to some embodiments, the body electrode of each of the first to sixth transistors T1 to T6 may be supplied with the first power supply voltage VDD. For example, the body electrodes of the first to sixth transistors T1 to T6 may be electrically connected to the first power line PL1 to which the first power supply voltage is supplied. The body electrode of each of the first to sixth transistors T1 to T6 may be formed by being mounted on a substrate SUB.

According to some embodiments, some of the transistors T1 to T6 may be formed of P-type transistors PT, and the others may be formed of N-type transistors NT. For example, the first to fifth transistors T1 to T5 may be formed of P-type transistors PT (e.g., P-channel Metal-Oxide-Semiconductor (PMOS)). The sixth transistor T6 may be formed of an N-type transistor NT (e.g., N-channel Metal-Oxide-Semiconductor (NMOS)). However, embodiments according to the present disclosure are not necessarily limited thereto.

The first transistor T1 may be connected between the fifth transistor T5 and a first node N1. The first electrode of the first transistor T1 may be connected to the second electrode of the fifth transistor T5, and the second electrode of the first transistor T1 may be connected to the first node N1. The gate electrode of the first transistor T1 may be connected to a second node N2. The first node N1 may be a node connected to the second electrode of the third transistor T3, and may be a node connected to the first electrode of the fourth transistor T4. The second node N2 may be a node connected to the first electrode of the third transistor T3, and may be a node connected to the second electrode of each of the first and second capacitors C1 and C2. The first transistor T1 may control the amount of current supplied from the first power supply voltage node VDDN that provides the first power supply voltage VDD to the second power supply voltage node VSSN that provides the second power supply voltage VSS via the light-emitting element LD in response to the voltage of the second node N2.

As used herein, being “connected” includes the meaning of being electrically connected.

The first transistor T1 may be a drive transistor.

The second transistor T2 may be electrically connected to the data line DLj. The second transistor T2 may be connected between the data line DLj and the first electrode of the first capacitor C1. The gate electrode of the second transistor T2 may be electrically connected to the first sub-gate line SGL1. The second transistor T2 may be turned on when a first gate signal GW is supplied to the first sub-gate line SGL1, and electrically connect the data line DLj and the first electrode of the first capacitor C1.

The second transistor T2 may be a switching transistor.

The third transistor T3 may be connected between the first node N1 and the second node N2. The gate electrode of the third transistor T3 may be electrically connected to the second sub-gate line SGL2. The third transistor T3 may be turned on when a second gate signal GC is supplied from the second sub-gate line SGL2, and electrically connect the first node N1 and the second node N2.

The third transistor T3 may be a compensation transistor.

The fourth transistor T4 may be connected between the first node N1 and the third node N3. The third node N3 may be a node connected to the anode electrode AE, and may be a node electrically connected to the first electrode of the sixth transistor T6. At least a portion of the third node N3 may be formed by a connection electrode COE. The gate electrode of the fourth transistor T4 may be electrically connected to the first sub-light emission control line SEL1i. The fourth transistor T4 may be turned on when a first light emission control signal EM1 is supplied from the first sub-light emission control line SEL1i, and electrically connect the first node N1 and the third node N3.

The fourth transistor T4 may be a first light emission control transistor.

The fifth transistor T5 may be connected between the first power line PL1 connected to the first power supply voltage node VDDN and the first electrode of the first transistor T1. The gate electrode of the fifth transistor T5 may be electrically connected to the second sub-light emission control line SEL2i. The fifth transistor T5 may be turned on when a second light emission control signal EM2 is supplied from the second sub-light emission control line SEL2i, and electrically connect the first power supply voltage node VDDN and the first electrode of the first transistor T1.

The fifth transistor T5 may be a second light emission control transistor.

The sixth transistor T6 may be connected between a third power line PL3 to which initialization power Vint (e.g., an initialization voltage) is supplied and the third node N3. The gate electrode of the sixth transistor T6 may be electrically connected to the third sub-gate line SGL3. The sixth transistor T6 may be turned on when a third gate signal EB is supplied from the third sub-gate line SGL3, and electrically connect the third node N3 and the third power line PL3.

The sixth transistor T6 may be an initialization transistor.

The first capacitor C1 may be connected between the second transistor T2 (e.g., the second electrode of the second transistor T2) and the second node N2. The second capacitor C2 may be connected between the first power supply voltage node VDDN and the second node N2.

According to some embodiments, the first and second capacitors C1 and C2 may have a structure of one of a MOM (metal-oxide-metal) capacitor and a MIM (metal-insulator-metal) capacitor. Alternatively, the first and second capacitors C1 and C2 may have a VNCAP (vertical native capacitor) structure. However, embodiments according to the present disclosure are not necessarily limited to any particular example.

Further, according to some embodiments, at least some of the P-type transistors PT and the N-type transistor NT may be formed to overlap in a same area. According to some embodiments, the P-type transistor PT and the N-type transistor NT connected to each other with a same node interposed therebetween may be formed so as to overlap in a same area.

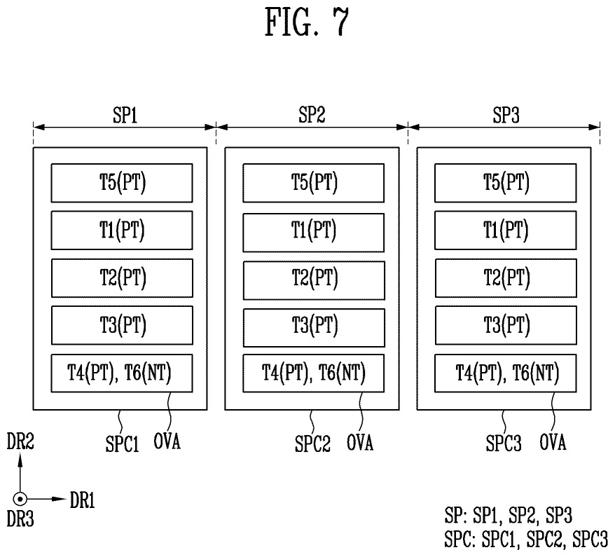

For example, according to some embodiments, the fourth transistor T4 having a P-type transistor PT structure and the sixth transistor T6 having an N-type transistor NT structure may be patterned to overlap in a same area. The detailed structure thereof will be described later with reference to the drawings that follow FIG. 7.

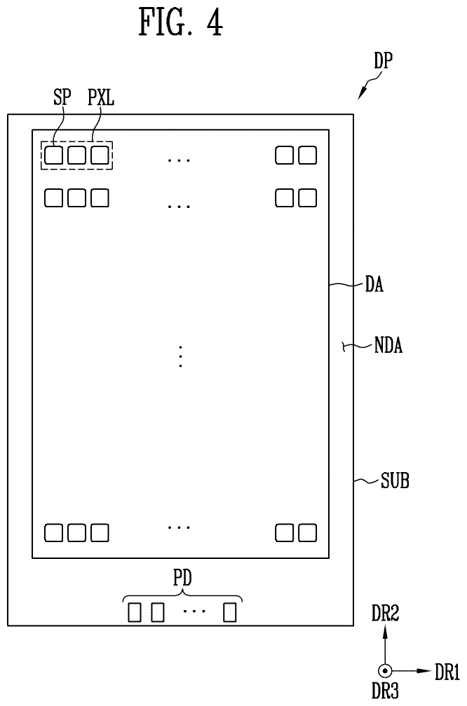

FIG. 4 is a plan view showing aspects of the display panel of FIG. 1 according to some embodiments.

Referring to FIG. 4, a display panel DP corresponding to the display panel 110 of FIG. 1 may include a display area DA and a non-display area NDA. The display panel DP displays images at the display area DA. The non-display area NDA is located at the periphery of (e.g., surrounding or outside a footprint of) the display area DA.

The display panel DP may include a substrate SUB, sub-pixels SP, and pads PD.

If the display panel DP is used as a display screen for a head-mounted display (HMD), a virtual reality (VR) device, a mixed reality (MR) device, an augmented reality (AR) device, etc., the display panel DP may be positioned very close to the user's eyes. In such a case, sub-pixels SP with a relatively high degree of integration are required. In order to increase the degree of integration of the sub-pixels SP, a silicon substrate may be provided as the substrate SUB. The sub-pixels SP may be formed on the substrate SUB, which is a silicon substrate. A display device 100 including the display panel DP including sub-pixels SP formed on the substrate SUB, which is a silicon substrate, may be referred to as an OLEDoS (OLED on Silicon) display device.

The sub-pixels SP are located in the display area DA on the substrate SUB. The sub-pixels SP may be arranged in a matrix form along a first direction DR1 and a second direction DR2 different from (e.g., intersecting) the first direction DR1. However, embodiments are not limited thereto. For example, the sub-pixels SP may be arranged in a zigzag form along the first direction DR1 and the second direction DR2. For example, the sub-pixels SP may be arranged in a Pentile™ form or arrangement. The first direction DR1 may be the row direction, and the second direction DR2 may be the column direction.

Two or more sub-pixels SP of a plurality of sub-pixels SP may make up a single pixel PXL.

Components for controlling the sub-pixels SP may be located in the non-display area NDA on the substrate SUB. For example, wiring lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, or the temperature sensor 160 of FIG. 1 may be integrated in the non-display area NDA of the display panel DP. According to some embodiments, the gate driver 120 of FIG. 1 may be mounted on the display panel DP but may be located in the non-display area NDA. According to some embodiments, the gate driver 120 may be implemented as an integrated circuit separate from the display panel DP. According to some embodiments, the temperature sensor 160 may be located in the non-display area NDA and sense the temperature of the display panel DP.

The pads PD are located in the non-display area NDA on the substrate SUB. The pads PD may be electrically connected to the sub-pixels SP through wiring lines. For example, the pads PD may be connected to the sub-pixels SP through the first to n-th data lines DL1 to DLn.

The pads PD can interface the display panel DP to other components of the display device 100. According to some embodiments, voltages and signals required for the operation of the components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power supply voltages VDD and VSS may be received from the driver integrated circuit DIC through the pads PD. For example, if the gate driver 120 is mounted on the display panel DP, the gate control signal GCS may be transmitted from the driver integrated circuit DIC to the gate driver 120 through the pads PD.

According to some embodiments, a circuit board may be electrically connected to the pads PD by using a conductive adhesive member such as an anisotropic conductive film. In this case, the circuit board may be a flexible circuit board FPCB or a flexible film having a flexible material. The driver integrated circuit DIC may be mounted on the circuit board and electrically connected to the pads PD.

According to some embodiments, the display area DA may have a variety of shapes. The display area DA may have the shape of a closed loop including straight and/or curved sides. For example, the display area DA may have shapes such as a polygon, a circle, a semicircle, an ellipse, etc.

According to some embodiments, the display panel DP may have a flat display surface. According to some embodiments, the display panel DP may have a display surface that is at least partially rounded. According to some embodiments, the display panel DP may be bendable, foldable, or rollable. In these cases, the display panel DP and/or the substrate SUB may contain materials having flexible properties.

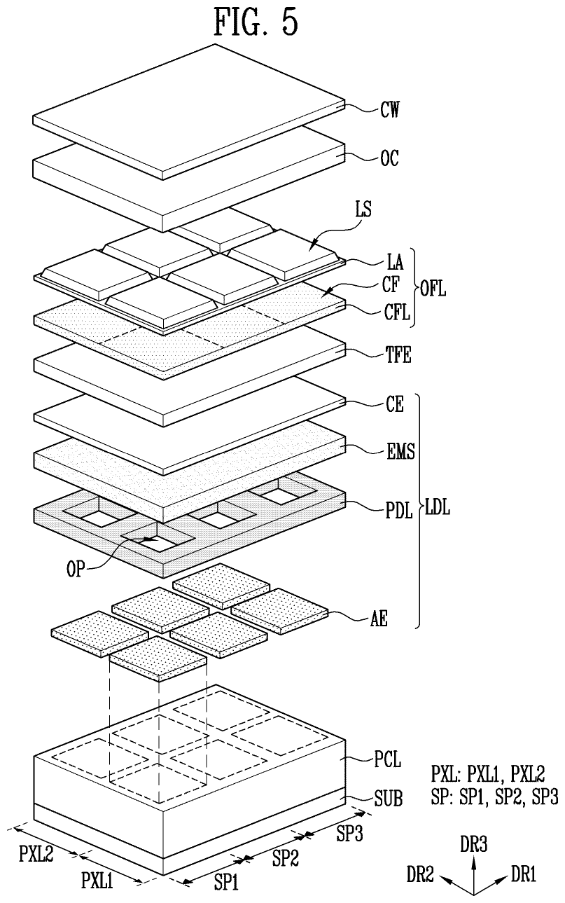

FIG. 5 is an exploded perspective view showing a portion of the display panel of FIG. 4. In FIG. 5, the portion of the display panel DP corresponding to two pixels PXL1 and PXL2 of the pixels PXL in FIG. 4 is shown schematically for clear and concise description. The portion of the display panel DP corresponding to the rest of the pixels PXL may be configured likewise.

Referring to FIGS. 4 and 5, the pixel PXL may include first and second pixels PXL1 and PXL2. The sub-pixel SP may include first to third sub-pixels SP1 to SP3. Each of the first and second pixels PXL1 and PXL2 may include first to third sub-pixels SP1, SP2, and SP3. However, embodiments according to the present disclosure are not limited thereto. For example, each of the first and second pixels PXL1 and PXL2 may include four sub-pixels, or may include two sub-pixels.

In FIG. 5, the first to third sub-pixels SP1, SP2, and SP3 are shown as having rectangular shapes when viewed in a third direction DR3 intersecting the first and second directions DR1 and DR2 (e.g., in a plan view), and having a same size as each other. However, embodiments according to the present disclosure are not limited thereto. The first to third sub-pixels SP1, SP2, and SP3 may be modified to have various shapes.

The display panel DP may include a substrate SUB, a pixel-circuit layer PCL, a light-emitting element layer LDL, an encapsulation layer TFE, an optical function layer OFL, an overcoat layer OC, and a cover window CW.

According to some embodiments, the substrate SUB may include a silicon wafer substrate formed using a semiconductor process. The substrate SUB may contain a semiconductor material suitable for forming circuit elements. For example, the semiconductor material may include silicon, germanium, and/or silicon-germanium. The substrate SUB may be provided from a bulk wafer, an epitaxial layer, an SOI (silicon on insulator) layer, a SeOI (semiconductor on insulator) layer, or the like. According to some embodiments, the substrate SUB may include a glass substrate. According to some embodiments, the substrate SUB may include a polyimide (PI) substrate.

The pixel-circuit layer PCL is located on the substrate SUB. The substrate SUB and/or the pixel-circuit layer PCL may include insulating layers and conductive patterns located between the insulating layers. The conductive patterns of the pixel-circuit layer PCL may function as at least some of the circuit elements, wiring lines, etc. The conductive patterns may contain copper, but embodiments are not limited thereto.

The circuit elements may include a sub-pixel circuit SPC of each of the first to third sub-pixels SP1, SP2, and SP3. The sub-pixel circuit SPC may include transistors and one or more capacitors. Each transistor may include a semiconductor portion including a first transistor electrode region, a second transistor electrode region, and a channel region, and a gate electrode overlapping the semiconductor portion. According to some embodiments, if the substrate SUB is provided by a silicon substrate, the semiconductor portion may be included in the substrate SUB, and the gate electrode may be included in the pixel-circuit layer PCL as a conductive pattern of the pixel-circuit layer PCL. According to some embodiments, if the substrate SUB is provided by a glass substrate or a PI substrate, the semiconductor portion and the gate electrode may be included in the pixel-circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The wiring lines of the pixel-circuit layer PCL may include signal lines connected to each of the first to third sub-pixels SP1, SP2, and SP3, for example, a gate line, a light emission control line, a data line, etc. The wiring lines may further include a wiring line connected to the first power supply voltage node VDDN of FIG. 2. In addition, the wiring lines may further include a wiring line connected to the second power supply voltage node VSSN of FIG. 2.

The light-emitting element layer LDL may include anode electrodes AE, a pixel-defining layer PDL, a emission structure EMS, and a cathode electrode CE.

The anode electrodes AE may be located on the pixel-circuit layer PCL. The anode electrodes AE may contact circuit elements of the pixel-circuit layer PCL. The anode electrodes AE may contain an opaque conductive material capable of reflecting light, but embodiments according to the present disclosure are not limited thereto.

The pixel-defining layer PDL is located on the anode electrodes AE. The pixel-defining layer PDL may include an opening OP exposing a portion of each of the anode electrodes AE. Light-emitting areas corresponding respectively to the first to third sub-pixels SP1 to SP3 can be defined according to the opening OP of the pixel-defining layer PDL. Alternatively, it may also be understood that light-emitting areas corresponding respectively to the first to third sub-pixels SP1 to SP3 are defined according to the anode electrodes AE. In a region adjacent to the boundary of neighboring sub-pixels, the pixel-defining layer PDL may include a separator that causes a discontinuity to be formed in the emission structure EMS. In such a case, it may also be understood that light-emitting areas corresponding respectively to the first to third sub-pixels SP1 to SP3 are defined according to the separators of the pixel-defining layer PDL.

According to some embodiments, the pixel-defining layer PDL may contain an inorganic material. In such a case, the pixel-defining layer PDL may include multiple stacked inorganic layers. For example, the pixel-defining layer PDL may contain silicon oxide (SiOx) and silicon nitride (SiNx). According to some embodiments, the pixel-defining layer PDL may contain an organic material. However, the material of the pixel-defining layer PDL is not limited thereto.

The emission structure EMS may be located on the anode electrodes AE exposed by the opening OP of the pixel-defining layer PDL. The emission structure EMS may include a light-emitting layer configured to generate light, an electron transport layer configured to transport electrons, a hole transport layer configured to transport holes, etc.

According to some embodiments, the emission structure EMS may fill the opening OP of the pixel-defining layer PDL, but may be arranged entirely on top of the pixel-defining layer PDL. In other words, the emission structure EMS may extend across the first to third sub-pixels SP1 to SP3. In such a case, at least some of the layers in the emission structure EMS may be broken or bent at the boundaries between the first to third sub-pixels SP1 to SP3. However, embodiments according to the present disclosure are not limited thereto. For example, the portions of the emission structure EMS corresponding to the first to third sub-pixels SP1 to SP3 may be separated from each other, and each of them may be located in the opening OP of the pixel-defining layer PDL.

The cathode electrode CE may be located on the emission structure EMS. The cathode electrode CE may extend across the first to third sub-pixels SP1 to SP3. In this way, the cathode electrode CE may be provided as a common electrode for the first to third sub-pixels SP1 to SP3.

The cathode electrode CE may be a thin metal layer having a thickness sufficient to transmit light emitted from the emission structure EMS. The cathode electrode CE may be formed of a metallic material or a transparent conductive material so as to have a relatively thin thickness. According to some embodiments, the cathode electrode CE may contain at least one of a variety of transparent conductive materials, including indium tin oxide, indium zinc oxide, indium tin zinc oxide, aluminum zinc oxide, gallium zinc oxide, zinc tin oxide, or gallium tin oxide. According to some embodiments, the cathode electrode CE may contain at least one of silver (Ag), magnesium (Mg), and/or a mixture thereof. However, the material of the cathode electrode CE is not limited thereto.

It can be understood that one of the anode electrodes AE, the portion of the emission structure EMS overlapping it, and the portion of the cathode electrode CE overlapping it constitute one light-emitting element LD. In other words, each of the light-emitting elements LD of the first to third sub-pixels SP1 to SP3 may include one anode electrode AE, the portion of the emission structure EMS overlapping it, and the portion of the cathode electrode CE overlapping it. In each of the first to third sub-pixels SP1 to SP3, holes injected from the anode electrode AE and electrons injected from the cathode electrode CE are transported into the light-emitting layer of the emission structure EMS and form excitons, and light can be generated when the excitons transition from the excited state to the ground state. The brightness of the light can be determined according to the amount of current flowing through the light-emitting layer. Depending on the configuration of the light-emitting layer, the wavelength range of the light generated can be determined.

According to some embodiments, the light-emitting element LD may be an organic light-emitting diode.

The encapsulation layer TFE is located on the cathode electrode CE. The encapsulation layer TFE may cover the light-emitting element layer LDL and/or the pixel-circuit layer PCL. The encapsulation layer TFE may be configured to prevent or reduce instances of contaminants such as oxygen and/or moisture, etc., infiltrating the light-emitting element layer LDL. According to some embodiments, the encapsulation layer TFE may include a structure in which one or more inorganic films and one or more organic films are stacked alternately. For example, the inorganic film may contain silicon nitride, silicon oxide, silicon oxynitride (SiOxNy), or the like. For example, the organic film may contain organic insulating materials, such as acrylic resins, epoxy resins, phenolic resins, polyamide resins, polyimide resins, unsaturated polyester resins, poly-phenylene ether resins, poly-phenylene sulfide resins, or benzocyclobutene (BCB). However, the materials of the organic film and inorganic film of the encapsulation layer TFE are not limited thereto.

In order to relatively improve the encapsulation efficiency of the encapsulation layer TFE, the encapsulation layer TFE may further include a thin film containing aluminum oxide (AlOx). The thin film containing aluminum oxide may be located on the top surface of the encapsulation layer TFE facing the optical function layer OFL and/or on the bottom surface of the encapsulation layer TFE facing the light-emitting element layer LDL.

The thin film containing aluminum oxide may be formed through an atomic layer deposition (ALD) method. However, embodiments according to the present disclosure are not limited thereto. The encapsulation layer TFE may further include a thin film formed of at least one of various materials suitable for relatively improving encapsulation efficiency.

The optical function layer OFL is located on the encapsulation layer TFE. The optical function layer OFL may include a color filter layer CFL and a lens array LA.

The color filter layer CFL is located between the encapsulation layer TFE and the lens array LA. The color filter layer CFL is configured to filter light emitted from the emission structure EMS and selectively output light of a wavelength range or color corresponding to each sub-pixel. The color filter layer CFL includes color filters CF corresponding to the first to third sub-pixels SP1 to SP3, respectively, and each of these color filters CF can pass light of a wavelength range corresponding to the relevant sub-pixel. For example, the color filter corresponding to the first sub-pixel SP1 can pass light of red color, the color filter corresponding to the second sub-pixel SP2 can pass light of green color, and the color filter corresponding to the third sub-pixel SP3 can pass light of blue color. Depending on the light emitted from the emission structure EMS of each sub-pixel, at least some of the color filters CF may be omitted.

The lens array LA is located on the color filter layer CFL. The lens array LA may include lenses LS corresponding to the first to third sub-pixels SP1 to SP3, respectively. Each of the lenses LS can relatively improve light emission efficiency by outputting the light emitted from the emission structure EMS to an intended path. The lens array LA may have a relatively high refractive index. For example, the lens array LA may have a higher refractive index than the overcoat layer OC. According to some embodiments, the lenses LS may contain an organic material. According to some embodiments, the lenses LS may contain an acrylic material. However, the material of the lenses LS is not limited thereto.

According to some embodiments, at least some of the color filters CF of the color filter layer CFL and at least some of the lenses LS of the lens array LA may be shifted in a direction parallel to the plane defined by the first and second directions DR1 and DR2, relative to the opening OP of the pixel-defining layer PDL. For example, in the central region of the display area DA, the center of the color filter CF and the center of the lens LS may be aligned or overlapped with the center of the opening OP of the corresponding pixel-defining layer PDL when viewed in the third direction DR3. For example, in the central region of the display area DA, the opening OP of the pixel-defining layer PDL may completely overlap the corresponding color filter CF of the color filter layer CFL and the corresponding lens LS of the lens array LA. In a region of the display area DA adjacent to the non-display area NDA, the center of the color filter CF and the center of the lens LS may be shifted in the planar direction from the center of the opening OP of the corresponding pixel-defining layer PDL when viewed in the third direction DR3. For example, in a region of the display area DA adjacent to the non-display area NDA, the opening OP of the pixel-defining layer PDL may partially overlap the corresponding color filter CF of the color filter layer CFL and the corresponding lens LS of the lens array LA. Accordingly, at the center of the display area DA, the light emitted from the emission structure EMS can be efficiently output in the normal direction of the display surface. In the periphery of the display area DA, the light emitted from the emission structure EMS can be relatively efficiently output in a direction tilted by an angle with respect to the normal direction of the display surface.

The overcoat layer OC may be located on the lens array LA. The overcoat layer OC may cover the optical function layer OFL, the encapsulation layer TFE, the emission structure EMS, and/or the pixel-circuit layer PCL. The overcoat layer OC may contain a variety of materials suitable for protecting the layers beneath it from foreign substances such as dust, moisture, etc. For example, the overcoat layer OC may include at least one of an inorganic insulating film or an organic insulating film. For example, the overcoat layer OC may contain epoxy, but embodiments are not limited thereto. The overcoat layer OC may have a lower refractive index than the lens array LA.

The cover window CW may be located on the overcoat layer OC. The cover window CW is configured to protect the layers beneath it. The cover window CW may have a higher refractive index than the overcoat layer OC. The cover window CW may include glass, but embodiments according to the present disclosure are not limited thereto. For example, the cover window CW may be an encapsulation glass configured to protect components located thereunder. According to some embodiments, the cover window CW may be omitted.

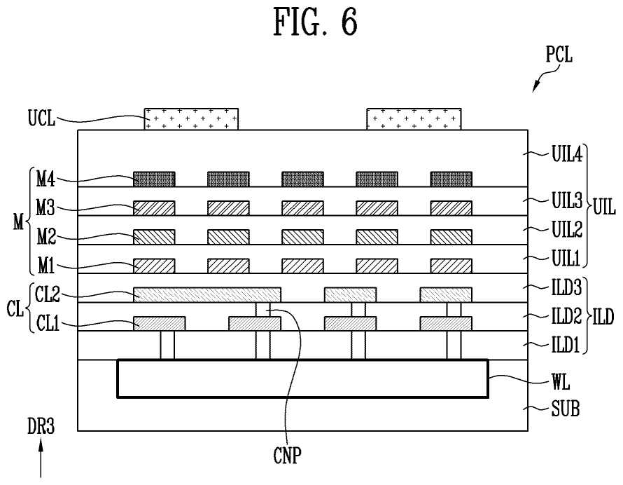

Referring to FIG. 6, the cross-sectional structure of the pixel-circuit layer PCL in which the circuit elements of the sub-pixel circuit SPC and wiring lines electrically connected to the sub-pixel circuit SPC according to some embodiments may be formed will be described in more detail.

FIG. 6 is a schematic cross-sectional view showing a pixel-circuit layer according to some embodiments.

According to some embodiments, the pixel-circuit layer PCL may include a well WL formed in a substrate SUB, and may also include conductive layers CL, conductive structure layers M, interlayer insulating layers ILD, upper insulating layers UIL, and an upper conductive layer UCL.

According to some embodiments, the circuit elements of the sub-pixel circuit SPC may be patterned on the substrate SUB.

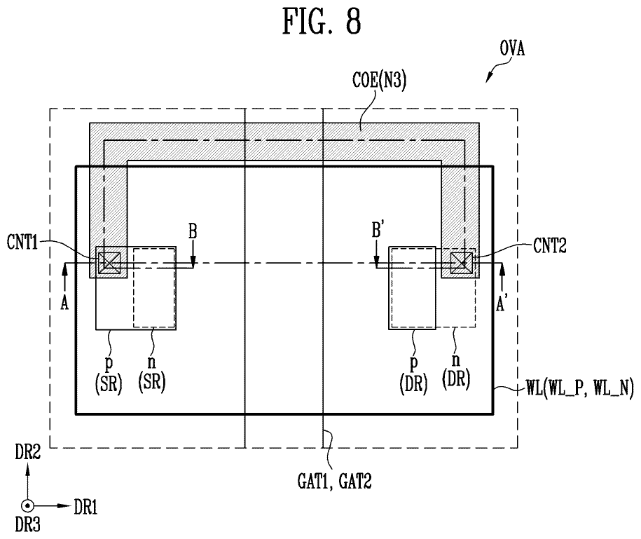

For example, the substrate SUB may be a silicon substrate, and a well WL formed through an ion implantation process may be located in the substrate SUB. A partial region of the well WL may form a first transistor electrode region SR (see FIG. 8) of the transistors T1 to T6, another partial region of the well WL may form a second transistor electrode region DR (see FIG. 8) of the transistors T1 to T6, and yet another partial region of the well WL may form a channel region of the transistors T1 to T6.

According to some embodiments, the first transistor electrode region SR in the present specification may be a source region, and the second transistor electrode region DR may be a drain region.

According to some embodiments, a portion of the well WL may be an N-type well WL_N (see FIG. 8). Another portion of the well WL may be a P-type well WL_P (see FIG. 8).

According to some embodiments, the conductive layers CL may form electrodes that are electrically connected to the first and second transistor electrode regions SR and DR of the transistors T1 to T6. According to some embodiments, the gate electrodes of some of the transistors T1 to T6 may be formed. For example, some of the conductive layers CL may form the gate electrodes of each of the first to third transistors T1 to T3 and the fifth transistor T5.

According to some embodiments, at least some of the conductive layers CL may be electrically connected to the well WL through contact members CNP. In addition, at least some of the conductive layers CL may form at least some of the first to third nodes N1 to N3 described above. Further, at least some of the conductive structure layers M may form at least some of the first to third nodes N1 to N3 described above. Accordingly, the substrate SUB and the conductive layers CL and conductive structure layers M on the substrate SUB may form the sub-pixel circuit SPC.

According to some embodiments, the conductive layers CL may form at least some of the lines electrically connected to the sub-pixel circuit SPC. For example, the conductive layers CL may form at least some of each of the first and second sub-gate lines SGL1 and SGL2, the light emission control line EL, the first power line PL1, and the third power line PL3.

According to some embodiments, some of the well WL, the conductive layers CL, and the conductive structure layers M may be electrically connected to each other through the contact members CNP that penetrate at least one of the interlayer insulating layers ILD or the upper insulating layers UIL. According to some embodiments, the upper conductive layer UCL may be electrically connected to at least some of the conductive layers CL and the conductive structure layers M, and accordingly, electrically connect the sub-pixel circuit SPC and the anode electrode AE of the light-emitting element LD.

According to some embodiments, the conductive layers CL may include first and second conductive layers CL1 and CL2. According to some embodiments, the interlayer insulating layers ILD may include first to third interlayer insulating layers ILD1 to ILD3. According to some embodiments, the conductive structure layers M may include first to fourth conductive structure layers M1 to M4. According to some embodiments, the upper insulating layers UIL may include first to fourth upper insulating layers UIL1 to UIL4. However, embodiments according to the present disclosure are not limited thereto. The number of layers forming each of the conductive layers CL, the conductive structure layers M, the interlayer insulating layers ILD, and the upper insulating layers UIL may be changed as appropriate.

According to some embodiments, the first to third interlayer insulating layers ILD1 to ILD3 and the first to fourth upper insulating layers UIL1 to UIL4 may be located, respectively, between some of the substrate SUB, the first and second conductive layers CL1 and CL2, the first to fourth conductive structure layers M1 to M4, and the upper conductive layer UCL.

According to some embodiments, the conductive layers CL and the conductive structure layers M may contain various conductive materials. The interlayer insulating layers ILD and the upper insulating layers UIL may contain an inorganic material. However, embodiments according to the present disclosure are not limited to any particular example.

According to some embodiments, the conductive structure layers M may be spaced further apart from the substrate SUB than the conductive layers CL. The conductive structure layers M may be spaced apart from the substrate SUB, and secure an opposing area between the electrodes forming the capacitors C1 and C2, so that a sufficient capacitance may be formed in the sub-pixel circuit SPC.

According to some embodiments, at least some of the conductive structure layers M may form at least some of the lines electrically connected to the sub-pixel circuit SPC. For example, at least one or more of the conductive structure layers M may form a data line DL. That is, the conductive layers CL and the conductive structure layers M may form the sub-pixel circuit SPC and lines electrically connected to the sub-pixel circuit SPC.

FIG. 7 is a diagram schematically showing adjacent sub-pixels and sub-pixel circuits.

Referring to FIG. 7, the sub-pixel circuit SPC may include a first sub-pixel circuit SPC1 included in the first sub-pixel SP1, a second sub-pixel circuit SPC2 included in the second sub-pixel SP2, and a third sub-pixel circuit SPC3 included in the third sub-pixel SP3.

The first to third sub-pixels SP1 to SP3 may be adjacent to each other. Accordingly, the first to third sub-pixel circuits SPC1 to SPC3 may be adjacent to each other. For example, the first to third sub-pixel circuits SPC1 to SPC3 may be adjacent along the first direction DR1.

According to some embodiments, the circuit elements of each of the sub-pixel circuits SPC may be adjacent along the first direction DR1. For example, a same type of transistors of each of the first to third sub-pixel circuits SPC1 to SPC3 may be adjacent to each other along the first direction DR1. For example, the first transistors T1 of each of the first to third sub-pixel circuits SPC1 to SPC3 may be adjacent along the first direction DR1.

The first to sixth transistors T1 to T6 may be arranged along the second direction DR2 different from the first direction DR1 in each of the first to third sub-pixel circuits SPC1 to SPC3.

According to some embodiments, in each of the sub-pixel circuits SPC, the P-type transistors PT may be arranged sequentially along the second direction DR2, and some of the P-type transistors PT and the N-type transistor NT may be arranged to overlap each other in an overlap area OVA.

For example, the fourth transistor T4 and the sixth transistor T6 may be arranged to overlap each other in the overlap area OVA, and the third transistor T3, the second transistor T2, the first transistor T1, and the fifth transistor T5 may be arranged (e.g., arranged sequentially) along the second direction DR2 above the overlap area OVA in a plan view.

The location of the overlap area OVA on the plane in the area formed by the sub-pixel circuit SPC is not particularly limited.

For example, the overlap area OVA may be formed on the lower side (e.g., the bottom side) in the area formed by the sub-pixel circuit SPC in a plan view, as shown in FIG. 7. The overlap area OVA being formed on the lower side (e.g., the bottom side) in the area formed by the sub-pixel circuit SPC in a plan view may mean that no other circuit elements are located further outside the overlap area OVA in a plan view. For example, the first to third transistors T1 to T3 and the fifth transistor T5 may not be located on one side (e.g., the lower side) of the overlap area OVA in a plan view along the second direction DR2. Alternatively, according to some embodiments, the overlap area OVA may be formed on the upper side or in the center in the area formed by the sub-pixel circuit SPC in a plan view. For example, at least one of the first to third transistors T1 to T3 and the fifth transistor T5 may be located on one side of the overlap area OVA in a plan view, and at least one other of the first to third transistors T1 to T3 and the fifth transistor T5 may be located on the other side of the overlap area OVA in a plan view.

According to some embodiments, because different types of transistors PT and NT may be located in the overlap area OVA, the area required for arranging the transistors T1 to T6 can be reduced. Accordingly, the area of the sub-pixel circuit SPC can be reduced, and the number of sub-pixels SP per unit area that operate based on the sub-pixel circuit SPC can be increased. Ultimately, according to some embodiments, a display device 100 capable of implementing high-resolution characteristics can be provided.

The structure of the display device 100 in the overlap area OVA will be described in greater detail with reference to FIGS. 8 to 10. FIGS. 8 to 10 show a structure in which the fourth transistor T4 and the sixth transistor T6 overlap each other in the overlap area OVA.

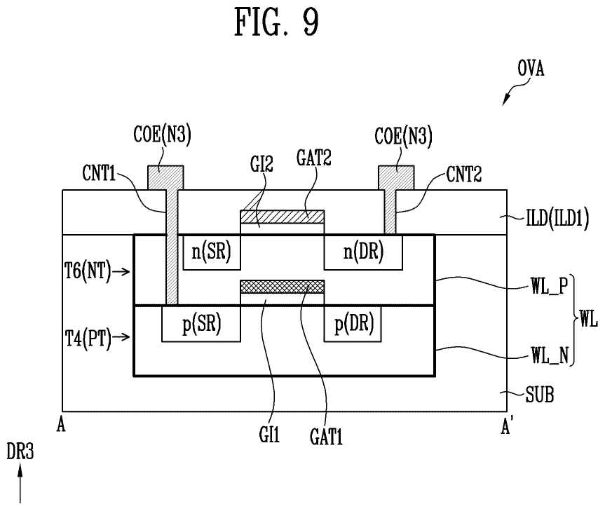

FIG. 8 is a schematic plan view showing a display device in an overlap area according to some embodiments. FIGS. 9 and 10 are schematic cross-sectional views showing a display device in an overlap area according to some embodiments. FIG. 9 is a schematic cross-sectional view taken along A-A′ in FIG. 8. FIG. 10 is a schematic cross-sectional view taken along B-B′ in FIG. 8. FIGS. 8 to 10 illustrate a substrate SUB and a first conductive layer CL1 on the substrate SUB in an overlap area OVA.

According to some embodiments, wells WL corresponding to each of a P-type transistor PT and an N-type transistor NT may overlap each other in a plan view. For convenience of description, the fourth transistor T4 is shown as an example of the P-type transistor PT and the sixth transistor T6 is shown as an example of the N-type transistor NT in the overlap area OVA in FIGS. 8 to 10. In the following, the description of the fourth transistor T4 can be understood as a description of the P-type transistor PT, and the description of the sixth transistor T6 can be understood as a description of the N-type transistor NT.

Referring to FIGS. 8 to 10, the wells WL may be formed in the substrate SUB in the overlap area OVA and may include an N-type well WL_N and a P-type well WL_P that overlap each other.

According to some embodiments, the substrate SUB may form a P-type well WL_P and an N-type well WL_N depending on the doped material (e.g., dopant). According to some embodiments, the substrate SUB may be a P-type substrate. A variety of materials known in general may be used as the N-type dopant or the P-type dopant. In addition, the method in which the dopant is doped may use any generally known process, such as an ion implantation process.

The N-type well WL_N may be formed below the P-type well WL_P in the overlap area OVA. The N-type well WL_N may be formed as an N-type dopant is provided (e.g., an ion implantation process) to at least a portion of the substrate SUB during the manufacturing process of the display device 100.

According to some embodiments, a first transistor electrode region SR and a second transistor electrode region DR of the P-type transistor PT (e.g., the fourth transistor T4) may be formed adjacent (e.g., directly adjacent) to the N-type well WL_N. For example, the first transistor electrode region SR and the second transistor electrode region DR of the P-type transistor PT (e.g., the fourth transistor T4) may be formed in a region surrounded by the N-type well WL_N. The first transistor electrode region SR and the second transistor electrode region DR of the P-type transistor PT (e.g., the fourth transistor T4) may overlap at least a portion of the N-type well WL_N along the planar direction. For example, P-type regions p may be formed by having a P-type dopant provided (e.g., an ion implantation process) to at least a portion of the N-type well WL_N. According to some embodiments, some of the P-type regions p adjacent to the N-type well WL_N may be the first transistor electrode regions SR of the P-type transistor PT, and the others of the P-type regions p adjacent to the N-type well WL_N may be the second transistor electrode regions DR of the P-type transistor PT.

The P-type region p may be referred to as a P-type dopant region.

According to some embodiments, the P-type transistor PT (e.g., the fourth transistor T4) may include a first gate electrode GAT1.

The first gate electrode GAT1 may be patterned after the N-type well WL_N and a first gate insulating layer GI1 on a portion of the N-type well WL_N are formed. The first gate electrode GAT1 may be located between the N-type well WL_N and the P-type well WL_P. The first gate electrode GAT1 may be located between the P-type regions p adjacent to the N-type well WL_N in a plan view, and accordingly, a channel region for forming the P-type transistor PT (e.g., the fourth transistor T4) may be formed between the first transistor electrode region SR and the second transistor electrode region DR.

According to some embodiments, the first gate electrode GAT1 may extend in the second direction DR2. The first gate electrode GAT1 may be located between the first transistor electrode region SR and the second transistor electrode region DR of the fourth transistor T4 along the first direction DR1. The first gate electrode GAT1 may be located between the first transistor electrode region SR and the second transistor electrode region DR of the sixth transistor T6 along the first direction DR1.

The first gate insulating layer GI1 may contain a material such as silicon oxide (SixOy), and may be located between the N-type well WL_N and the first gate electrode GAT1.

The P-type well WL_P may be formed on top of the N-type well WL_N in the overlap area OVA. The P-type well WL_P may be formed as a P-type dopant is provided (e.g., an ion implantation process) to at least a portion of the substrate SUB (e.g., on top of the N-type well WL_N) during the manufacturing process of the display device 100.

According to some embodiments, the first transistor electrode region SR and the second transistor electrode region DR of the N-type transistor NT (e.g., the sixth transistor T6) may be formed adjacent (e.g., directly adjacent) to the P-type well WL_P. For example, the first transistor electrode region SR and the second transistor electrode region DR of the N-type transistor NT (e.g., the sixth transistor T6) may be formed in a region surrounded by the P-type well WL_P. The first transistor electrode region SR and the second transistor electrode region DR of the N-type transistor NT (e.g., the sixth transistor T6) may overlap at least a portion of the P-type well WL_P along the planar direction. For example, N-type regions n may be formed by having an N-type dopant provided (e.g., an ion implantation process) to at least a portion of the P-type well WL_P. According to some embodiments, some of the N-type regions n adjacent to the P-type well WL_P may be the first transistor electrode regions SR of the N-type transistor NT, and the others of the N-type regions n adjacent to the P-type well WL_P may be the second transistor electrode regions DR of the N-type transistor NT.

The N-type region n may be referred to as an N-type dopant region.

According to some embodiments, the N-type transistor NT (e.g., the sixth transistor T6) may include a second gate electrode GAT2.

The second gate electrode GAT2 may be patterned after the P-type well WL_P and a second gate insulating layer GI2 on a portion of the P-type well WL_P are formed. The second gate electrode GAT2 may be located between the N-type regions n adjacent to the P-type well WL_P in a plan view, and accordingly, a channel region for forming the N-type transistor NT (e.g., the sixth transistor T6) may be formed between the first transistor electrode region SR and the second transistor electrode region DR.

According to some embodiments, the second gate electrode GAT2 may extend in the second direction DR2. The second gate electrode GAT2 may be located between the first transistor electrode region SR and the second transistor electrode region DR of the fourth transistor T4 along the first direction DR1. The second gate electrode GAT2 may be located between the first transistor electrode region SR and the second transistor electrode region DR of the sixth transistor T6 along the first direction DR1.

According to some embodiments, the first and second gate electrodes GAT1 and GAT2 may overlap each other in a plan view. For example, the first and second gate electrodes GAT1 and GAT2 may be patterned in a same area in a plan view. However, embodiments according to the present disclosure are not limited thereto.

The second gate insulating layer GI2 may contain a material such as silicon oxide (SixOy), and may be located between the P-type well WL_P and the second gate electrode GAT2.

According to some embodiments, the display device 100 may include a connection electrode COE for electrically connecting the N-type transistor NT and the P-type transistor PT to each other.

The connection electrode COE may electrically connect the fourth transistor T4 and the sixth transistor T6. The connection electrode COE may form at least a portion of the third node N3. According to some embodiments, no other transistor may be formed between the N-type transistor NT and the P-type transistor PT, and the N-type transistor NT and the P-type transistor PT may be electrically connected by the connection electrode COE (i.e., the third node N3).

The connection electrode COE may be formed by the first conductive layer CL1 described above with reference to FIG. 6. The connection electrode COE may be located on the substrate SUB, and may be located on an interlayer insulating layer ILD (e.g., the first interlayer insulating layer ILD1) that covers the second gate electrode GAT2.

However, embodiments according to the present disclosure are not necessarily limited thereto. The connection electrode COE1 may be formed by another conductive structure of the pixel-circuit layer PCL other than the first conductive layer CL1.

According to some embodiments, the connection electrode COE may include portions extending in two or more directions in a plan view. For example, the connection electrode COE may include a first portion extending in the second direction DR2 and electrically connected to the first transistor electrode region SR of the fourth transistor T4, a second portion extending in the second direction DR2 and electrically connected to the second transistor electrode region DR of the sixth transistor T6, and a third portion extending in the first direction DR1 different from the second direction DR2 and connecting the first portion and the second portion. In this case, at least a portion (e.g., the third portion) of the connection electrode COE may not overlap the well WL in a plan view.

A portion (e.g., the first portion) of the connection electrode COE may be electrically connected to a portion of the fourth transistor T4. For example, a portion of the connection electrode COE may be electrically connected to the first transistor electrode region SR of the fourth transistor T4 through a first contact portion CNT1 that penetrates the interlayer insulating layer ILD and the P-type well WL_P.

According to some embodiments, the first transistor electrode region SR of the fourth transistor T4 may overlap the first transistor electrode region SR of the sixth transistor T6 in a plan view. Further, at least a portion of the first transistor electrode region SR of the fourth transistor T4 may not overlap the first transistor electrode region SR of the sixth transistor T6 in a plan view.

The first transistor electrode region SR of the sixth transistor T6 may expose at least a portion of the first transistor electrode region SR of the fourth transistor T4 in a plan view. Accordingly, the first contact portion CNT1 can penetrate the P-type well WL_P by avoiding the first transistor electrode region SR of the sixth transistor T6 and can be connected to the first transistor electrode region SR of the fourth transistor T4.

According to some embodiments, the first transistor electrode region SR of the fourth transistor T4 may be formed in an area larger than the first transistor electrode region SR of the sixth transistor T6. The second transistor electrode region DR of the fourth transistor T4 may be formed in an area smaller than the second transistor electrode region DR of the sixth transistor T6.

Another portion (e.g., the second portion) of the connection electrode COE may be electrically connected to a portion of the sixth transistor T6. For example, another portion of the connection electrode COE may be electrically connected to the second transistor electrode region DR of the sixth transistor T6 through a second contact portion CNT2 that penetrates the interlayer insulating layer ILD. According to some embodiments, the second transistor electrode region DR of the fourth transistor T4 may overlap the second transistor electrode region DR of the sixth transistor T6 in a plan view. Further, at least a portion of the second transistor electrode region DR of the sixth transistor T6 may not overlap the second transistor electrode region DR of the fourth transistor T4 in a plan view.

Accordingly, the connection electrode COE may electrically connect the first transistor electrode region SR of the fourth transistor T4 and the second transistor electrode region DR of the sixth transistor T6, and form at least a portion of the third node N3.

Ultimately, according to some embodiments, at least a portion of each of the P-type transistor PT and the N-type transistor NT in the sub-pixel circuit SPC can be formed to overlap each other, and a display device 100 capable of implementing high-resolution characteristics can be provided.

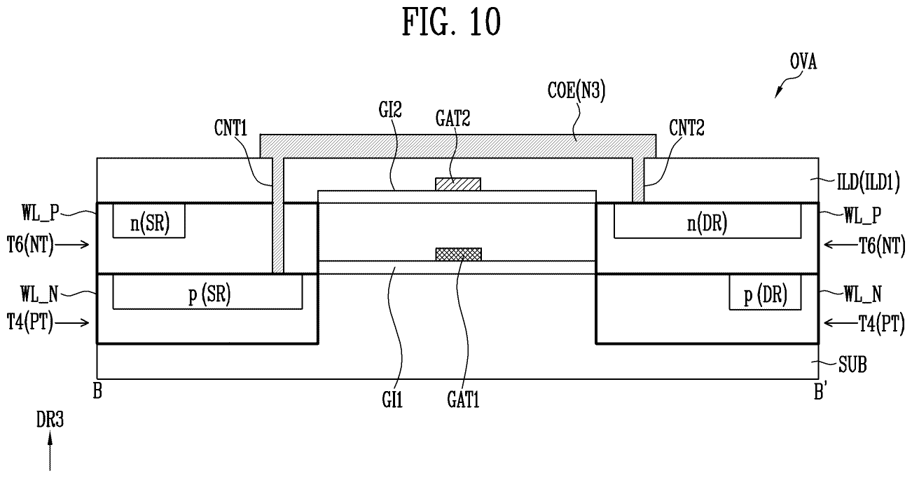

FIG. 11 is a block diagram showing aspects of an electronic device according to some embodiments.

Referring to FIG. 11, an electronic device 1000 may include a processor 1100 and one or more display devices 1210 and 1220.

The processor 1100 can perform various tasks and computations. According to some embodiments, the processor 1100 may include an application processor, a graphic processor, a microprocessor, a central processing unit (CPU), etc. The processor 1100 may be connected to other components of the electronic device 1000 through a bus system and control them.

According to an embodiment, the processor 1100 may provide input image data to the display device 1210, 1220, and the display device 1210, 1220 may display images based on the input image data provided by the processor 1100.

In FIG. 11, the electronic device 1000 is shown as including first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 can display an image based on the first image data IMG1 and the first control signal CTRL1. The first display device 1210 may be configured similarly to the display device 100 described with reference to FIG. 1. In such a case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 can display an image based on the second image data IMG2 and the second control signal CTRL2. The second display device 1220 may be configured similarly to the display device 100 described with reference to FIG. 1. In such a case, the second image data IMG2 and the second control signal CTRL2 may be provided as the input image data IMG and the control signal CTRL of FIG. 1, respectively.

The electronic device 1000 may include a computing system that provides an image display function, such as a portable computer, a mobile phone, a smartphone, a tablet personal computer, and a smartwatch, a watch phone, a portable multimedia player (PMP), a navigation system, an ultra-mobile personal computer (UMPC), etc. In addition, the electronic device 1000 may include at least one of a head-mounted display (HMD), a virtual reality (VR) device, a mixed reality (MR) device, or an augmented reality (AR) device.

According to an embodiment, the electronic device 1000 may further include a memory device, a storage device, an input/output(I/O) device, a power supply.

The memory device may store data needed to perform the operation of the electronic device 1000. The memory device may function as a working memory and/or a buffer memory for the processor 1100. For example, the memory device may include one or more volatile memory devices such as a dynamic random access memory (DRAM) device, a static random access memory (SRAM) device, and a mobile DRAM device.

The storage device may store data in response to control signals or data from the processor 1100. The storage device may include one or more non-volatile storages to retain the data even when the electronic device 1000 is powered off. In some embodiments, the storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

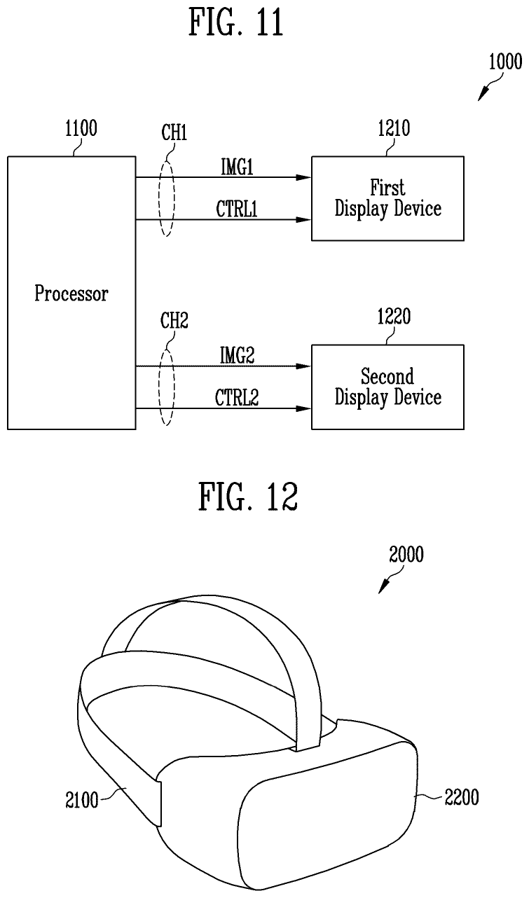

FIG. 12 is a perspective view showing an application example of the electronic device of FIG. 11.

Referring to FIG. 12, the electronic device 1000 of FIG. 11 can be applied to a head-mounted display 2000. The head-mounted display 2000 may be a wearable electronic device that can be worn on a user's head.

The head-mounted display 2000 may include a head-mounted band 2100 and a display device storage case 2200. The head-mounted band 2100 may be connected to the display device storage case 2200. The head-mounted band 2100 may include a horizontal band and/or a vertical band for securing the head-mounted display 2000 to the user's head. The horizontal band may be configured to surround the sides of the user's head, and the vertical band may be configured to surround the top of the user's head. However, embodiments are not limited thereto. For example, the head-mounted band 2100 may be implemented in the form of a glasses frame, a helmet, etc.

The display device storage case 2200 may store the first and second display devices 1210 and 1220 of FIG. 11. The display device storage case 2200 may further store the processor 1100 of FIG. 11.

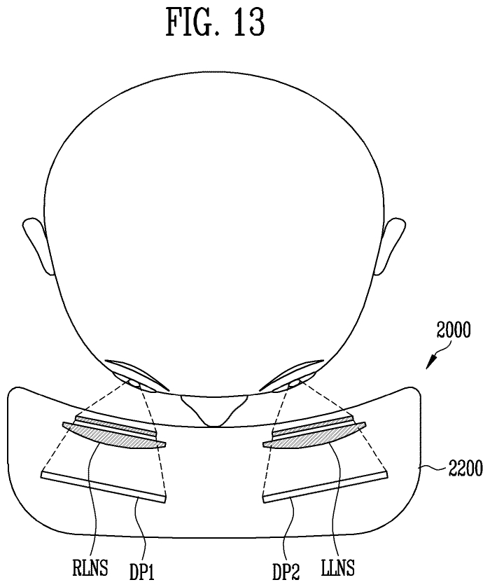

FIG. 13 is a diagram showing the head-mounted display worn by a user of FIG. 12.

Referring to FIG. 13, a first display panel DP1 of the first display device 1210 and a second display panel DP2 of the second display device 1220 are located in the head-mounted display 2000. The head-mounted display 2000 may further include one or more lenses LLNS and RLNS.

In the display device storage case 2200, a right-eye lens RLNS may be located between the first display panel DP1 and the user's right eye. In the display device storage case 2200, a left-eye lens LLNS may be located between the second display panel DP2 and the user's left eye.

An image outputted from the first display panel DP1 may be shown to the user's right eye through the right-eye lens RLNS. The right-eye lens RLNS can refract light from the first display panel DP1 toward the user's right eye. The right-eye lens RLNS can perform an optical function for adjusting the viewing distance between the first display panel DP1 and the user's right eye.

An image outputted from the second display panel DP2 may be shown to the user's left eye through the left-eye lens LLNS. The left-eye lens LLNS can refract light from the second display panel DP2 toward the user's left eye. The left-eye lens LLNS can perform an optical function for adjusting the viewing distance between the second display panel DP2 and the user's left eye.

According to some embodiments, each of the right-eye lens RLNS and the left-eye lens LLNS may include an optical lens having a pancake-shaped cross-section. According to some embodiments, each of the right-eye lens RLNS and the left-eye lens LLNS may include a multi-channel lens including sub-regions having different optical properties. In such a case, each display panel may output images corresponding, respectively, to the sub-regions of the multi-channel lens, and the output images may be shown to the user by passing through the corresponding sub-regions, respectively.

Although particular embodiments and application examples have been described herein, other embodiments and modifications can be derived from the above description. Therefore, the spirit and scope of embodiments according to the present disclosure are not limited to these embodiments, but extend to the claims set forth below, and their equivalents.

What is claimed is:

1. A display device comprising:
a sub-pixel circuit on a substrate and comprising an N-type transistor and a P-type transistor, each including a first transistor electrode region and a second transistor electrode region, and a connection electrode; and
a light-emitting element electrically connected to the sub-pixel circuit,
wherein the substrate comprises a well including an N-type well and a P-type well that overlap each other in a plan view,
the first transistor electrode region and the second transistor electrode region of the P-type transistor are P-type regions formed in the N-type well,
the first transistor electrode region and the second transistor electrode region of the N-type transistor are N-type regions formed in the P-type well, and
the connection electrode electrically connects the first transistor electrode region of the P-type transistor and the second transistor electrode region of the N-type transistor.

2. The display device of claim 1, wherein the P-type well is on the N-type well.

3. The display device of claim 2, wherein the first transistor electrode region is a source region,
the second transistor electrode region is a drain region,
the P-type transistor comprises a first gate electrode,
the N-type transistor comprises a second gate electrode, and
the first gate electrode is between the N-type well and the P-type well.

4. The display device of claim 3, wherein the first gate electrode and the second gate electrode overlap each other in the plan view.

5. The display device of claim 3, wherein the first gate electrode is between the first transistor electrode region and the second transistor electrode region of the N-type transistor in the plan view.

6. The display device of claim 5, wherein the second gate electrode is between the first transistor electrode region and the second transistor electrode region of the P-type transistor in the plan view.

7. The display device of claim 6, wherein the connection electrode forms at least a portion of a node that electrically connects the N-type transistor and the P-type transistor, and
no other transistor is formed between the N-type transistor and the P-type transistor.

8. The display device of claim 7, wherein the connection electrode is on the substrate, and is on an interlayer insulating layer covering the second gate electrode.

9. The display device of claim 7, wherein the connection electrode comprises a first portion extending in a second direction and electrically connected to the first transistor electrode region of the P-type transistor, a second portion extending in the second direction and electrically connected to the second transistor electrode region of the N-type transistor, and a third portion extending in a first direction different from the second direction and connecting the first portion and the second portion.

10. The display device of claim 9, wherein the first gate electrode and the second gate electrode extend in the second direction.

11. The display device of claim 9, wherein the first portion of the connection electrode is electrically connected to the first transistor electrode region of the P-type transistor through a first contact part, and
the second portion of the connection electrode is electrically connected to the second transistor electrode region of the N-type transistor through a second contact part.

12. The display device of claim 1, wherein a portion of the first transistor electrode region of the P-type transistor overlaps a portion of the first transistor electrode region of the N-type transistor in the plan view, and
another portion of the first transistor electrode region of the P-type transistor does not overlap at least another portion of the first transistor electrode region of the N-type transistor in the plan view.

13. The display device of claim 12, wherein a portion of the second transistor electrode region of the N-type transistor overlaps a portion of the second transistor electrode region of the P-type transistor in the plan view, and
another portion of the second transistor electrode region of the N-type transistor does not overlap at least another portion of the second transistor electrode region of the P-type transistor in the plan view.

14. The display device of claim 1, wherein the sub-pixel circuit comprises a first sub-pixel circuit, a second sub-pixel circuit, and a third sub-pixel circuit, each of which comprises circuit elements including the N-type transistor and the P-type transistor and which are adjacent to each other along a first direction, and
the circuit elements are arranged along a second direction different from the first direction in each of the first sub-pixel circuit, the second sub-pixel circuit, and the third sub-pixel circuit.

15. The display device of claim 14, further comprising:
a first power line, a second power line, a third power line, and a data line that are electrically connected to the sub-pixel circuit,
wherein the first power line forms a first power supply voltage node, and the second power line forms a second power supply voltage node,
the P-type transistor is a P-channel Metal-Oxide-Semiconductor (PMOS),
the N-type transistor is an N-channel Metal-Oxide-Semiconductor (NMOS),
the sub-pixel circuit comprises a first transistor, a second transistor, a third transistor, a fourth transistor, a fifth transistor, and a sixth transistor,
the first transistor is connected between the fifth transistor and a first node,
the second transistor is electrically connected to the data line,
the third transistor is connected between a second node electrically connected to a gate electrode of the first transistor and the first node,
the fourth transistor is connected between a third node electrically connected to an anode electrode of the light-emitting element and the first node,
the fifth transistor is connected between the first transistor and the first power line,
the sixth transistor is connected between the third node and the third power line,
a cathode electrode of the light-emitting element is connected between the second power line and the third node,
the fourth transistor is the P-type transistor, and
the sixth transistor is the N-type transistor.

16. The display device of claim 15, wherein the P-type transistor and the N-type transistor overlap in an overlap area in the plan view, and
the first transistor, the second transistor, the third transistor, and the fifth transistor are on one side of the overlap area.

17. The display device of claim 16, wherein the first transistor, the second transistor, the third transistor, and the fifth transistor are not on the other side of the overlap area along the second direction.

18. The display device of claim 15, wherein no other transistor is formed between the fourth transistor and the sixth transistor.

19. The display device of claim 15, wherein the sub-pixel circuit further comprises:
a first capacitor connected between the second transistor and the second node; and
a second capacitor connected between the first power supply voltage node and the second node, and
wherein each of the first transistor, the second transistor, the third transistor, the fourth transistor, the fifth transistor, and the sixth transistor comprises a body electrode mounted on the substrate and electrically connected to the first power line, and
the display device is an OLEDoS (OLED on Silicon) display device.

20. A pixel circuit comprising:
a P-type transistor including a first gate electrode; and
an N-type transistor including a second gate electrode,
wherein no other transistor is formed between the N-type transistor and the P-type transistor, and the N-type transistor and the P-type transistor are electrically connected through one node, and
the first gate electrode and the second gate electrode overlap each other in a plan view.

21. An electronic device, comprising:
a processor configured to provide input image data;
a display device configured to display an image based on the input image data, the display device including sub-pixel areas; and
a power supply configured to supply power to the display device,
wherein the display device comprises:
a sub-pixel circuit on a substrate and comprising an N-type transistor and a P-type transistor, each including a first transistor electrode region and a second transistor electrode region, and a connection electrode; and
a light-emitting element electrically connected to the sub-pixel circuit,
wherein the substrate comprises a well including an N-type well and a P-type well that overlap each other in a plan view,
the first transistor electrode region and the second transistor electrode region of the P-type transistor are P-type regions formed in the N-type well,
the first transistor electrode region and the second transistor electrode region of the N-type transistor are N-type regions formed in the P-type well, and
the connection electrode electrically connects the first transistor electrode region of the P-type transistor and the second transistor electrode region of the N-type transistor.
